(19) United States
(12) Patent Application Publication
(10) Pub. No.: US 2025/0176148 A1
(43) Pub. Date: May 29, 2025

(54) ENERGY STORAGE SYSTEM AND HEAT DISSIPATION SYSTEM

(71) Applicant: Jinko Energy Storage Technology Co., Ltd., Haining (CN)

(72) Inventor: Jian YU, Haining (CN)

(21) Appl. No.: 18/731,410

(22) Filed: Jun. 3, 2024

(30) Foreign Application Priority Data
Nov. 24, 2023 (CN) 202311586932.4

(51) Int. Cl. H05K 7/20; H05K 5/02

(52) U.S. Cl. CPC H05K 7/20909; H05K 5/0213; H05K 7/20145; H05K 7/20172

(57) ABSTRACT

An energy storage system, including a box, a cavity is provided in the box, a fan, a mounting member, and a first heating member are provided in the cavity. The fan and the mounting member are mounted on the inner wall of the cavity and the mounting member is located on an air outlet side of the fan. The first heating member is mounted on one side of the mounting member along a thickness direction of the mounting member. The mounting member is provided with a vent, an air guiding member is provided on a side of the vent away from the fan. The air guiding member bends away from the first heating member and extends towards the fan, so that airflow on the other side of the mounting member can flow along the air guiding member to a side of the mounting member having the first heating member.

### CROSS-REFERENCE TO RELATED APPLICATION

The present application claims priority to Chinese Patent Application No. 202311586932.4, filed Nov. 24, 2023, the content of which is incorporated herein by reference in its entirety.

### TECHNICAL FIELD

The present disclosure relates to the technical field of energy storage, and in particular, to an energy storage system and a heat dissipation system.

### BACKGROUND

An energy storage system may control charging and discharging processes of a battery, which performs alternating current/direct current (AC/DC) conversion, and directly supply power to AC loads when there is no power grid available. During operation, many elements in the energy storage system will dissipate heat, a heat sink cannot directly dissipate heat due to limitation of size of the energy storage system, causing the temperature inside the energy storage system to rise.

### SUMMARY

The present disclosure provides an energy storage system and a heat dissipation system to solve the problem of poor heat dissipation in the energy storage system.

The present disclosure provide an energy storage system, the energy storage system includes: a box including a cavity provided therein; a fan located in the cavity and mounted on an inner wall of the cavity; a mounting member connected to the inner wall of the cavity and located on an air outlet side of the fan; and a first heating member mounted on one side of the mounting member along a thickness direction of the mounting member. The fan is configured to increase air flow rates on two sides of the mounting member along the thickness direction, the mounting member includes a vent, the vent runs through the mounting member along the thickness direction, an air guiding member is provided on a side wall of the vent away from the fan. Along the thickness direction of the mounting member, the air guiding member bends away from the first heating member and extends towards the fan.

In some embodiments, the first heating member includes a circuit board and a heating element mounted on the circuit board, and the mounting member is provided with the vent at a position corresponding to the heating element.

In some embodiments, the heating element is mounted on a side of the circuit board away from the mounting member, a support member is arranged between the circuit board and the mounting member, and the support member is configured to support the circuit board.

In some embodiments, the energy storage system further includes a second heating member located, along the thickness direction of the mounting member, on a side of the mounting member away from the first heating member.

In some embodiments, the fan is located on a side of the mounting member along a length direction of the mounting member, the mounting member is provided with a plurality of vents arranged at intervals along a width direction of the mounting member, and along an air outlet direction of the fan, the vents and the second heating member are sequentially arranged.

In some embodiments, the mounting member is provided with a plurality of vents arranged at intervals along a length direction of the mounting member, and along a direction perpendicular to an air outlet direction of the fan, the vents and the second heating member are arranged side by side.

In some embodiments, an angle between the air guiding member and the mounting member ranges from 132° to 138°.

In some embodiments, an extension portion is arranged at an end of the air guiding member away from the mounting member, and the extension portion bends towards to the fan and away from the first heating member.

In some embodiments, an angle between a straight line where the extension portion is located and the mounting member ranges from 0° to 90°.

In some embodiments, a cross section of the extension portion is in a shape of an arc.

The present disclosure further provide a heat dissipation system, the heat dissipation system is applied to the energy storage system according to any one of the above embodiments, the heat dissipation system includes a first heat dissipation channel and a second heat dissipation channel. Along the thickness direction of the mounting member, the first heat dissipation channel is located on a side of the mounting member close to the first heating member, the second heat dissipation channel is located on a side of the mounting member away from the first heating member. The first heat dissipation channel and the second heat dissipation channel are communicated through the vent, so that airflow in the second heat dissipation channel passes through the vent and enters the first heat dissipation channel.

It should be understood that the above general description and the following detailed description are only exemplary and do not limit the present disclosure.

### BRIEF DESCRIPTION OF DRAWINGS

FIG. 1 is a top view of an energy storage system according to some embodiments of the present disclosure;

FIG. 2 is a sectional view taken along a direction A-A in FIG. 1;

FIG. 3 is a partial schematic structural diagram of a mounting member according to some embodiments of the present disclosure;

FIG. 4 is a side view of the energy storage system according to some embodiments of the present disclosure;

FIG. 5 is a sectional view taken along a direction B-B in FIG. 4;

FIG. 6 is a top view of the mounting member according to some embodiments of the present disclosure;

FIG. 7 is a partial schematic structural diagram in a sectional view taken along the direction B-B in FIG. 4;

FIG. 8 is a partial sectional view of the mounting member according to some embodiments of the present disclosure; and

FIG. 9 is a schematic diagram of a heat dissipation system according to some embodiments of the present disclosure.

The accompanying drawings, which are incorporated in and constitute a part of the specification, illustrate embodiments consistent with the present disclosure and together with the description serve to explain the principles of the present disclosure.

### DESCRIPTION OF EMBODIMENTS

In order to better understand the technical solution of the present disclosure, the embodiments of the present disclosure will be described in detail below with reference to the accompanying drawings.

It should be noted that the described embodiments are only some of, rather than all of the embodiments of the present disclosure. Based on the embodiments in the present disclosure, all other embodiments obtained by those of ordinary skill in the art without making creative efforts shall fall within the protection scope of the present disclosure.

The terms used in the embodiments of the present disclosure are for the purpose of describing embodiments only and are not intended to limit the present disclosure. As used in the embodiments of the present disclosure and the appended claims, the singular forms “a,” “an”, and “the” are intended to include the plural forms as well, unless the context clearly dictates otherwise.

It should be understood that the term “and/or” used herein is merely an association relationship describing associated objects, indicating that there may be three relationships. For example, A and/or B may indicate that there are three cases of A alone, A and B together, and B alone. In addition, the character “/” herein generally indicates that the related objects before and after the character form an “or” relationship.

It should be noted that, the directional terms such as “above” or “below”, “left”, and “right” described in the embodiments of the present disclosure are described from the perspectives shown in the accompanying drawings, and should not be construed as limiting the embodiments of the present disclosure. In addition, it should also be understood that, in the context, while an element is referred to as being formed “above” or “below” another element, it is possible that the element is directly formed “above” or “below” another element, it is also possible that the element is formed “above” or “below” another element via an intermediate element.

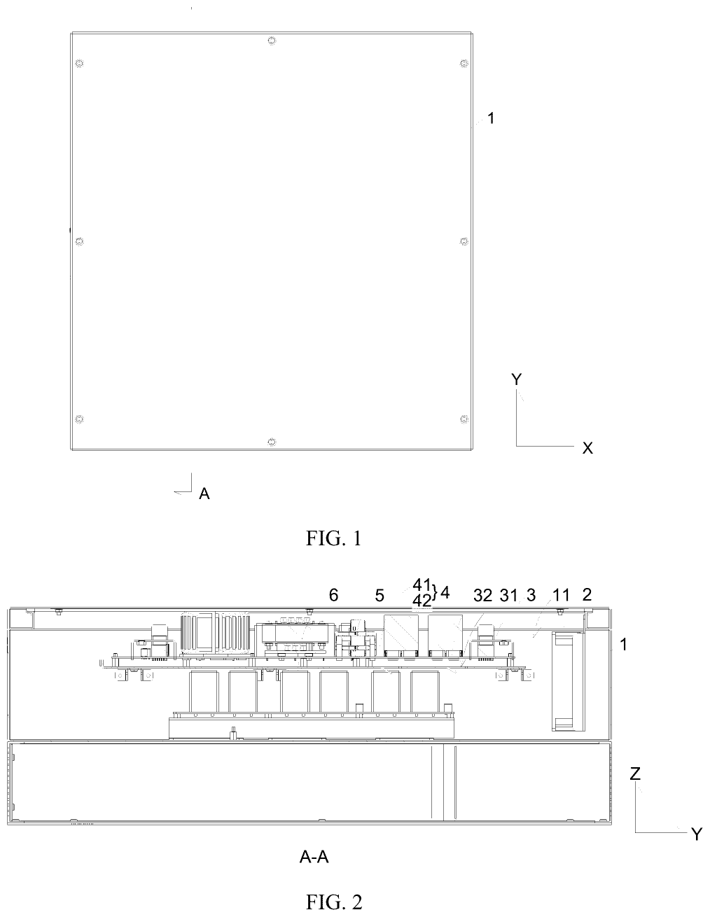

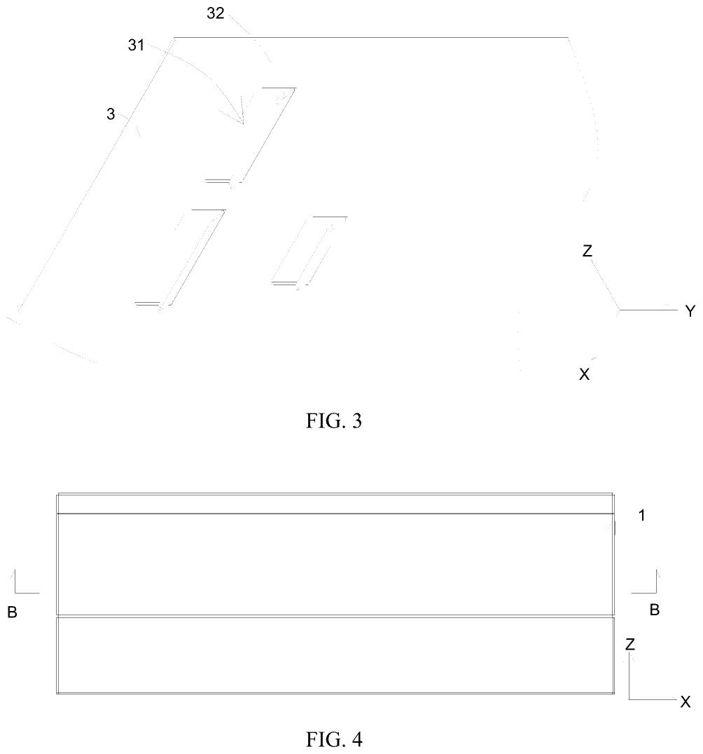

As shown in FIG. 1, FIG. 2, and FIG. 3, some embodiments of the present disclosure provide an energy storage system, including a box 1, a fan 2, a mounting member 3, and a heating member 4. A cavity 11 is provided in the box 1. The fan 2 is located in the cavity 11 and is mounted on an inner wall of the cavity 11. The mounting member 3 is connected to the inner wall of the cavity 11 and is located on an air outlet side of the fan 2. The first heating member 4 is mounted on one side of the mounting member 3 along a thickness direction Z of the mounting member 3. The fan 2 is configured to increase air flow rates on two sides of the mounting member 3 in the thickness direction Z. The mounting member 3 includes a vent 31. The vent 31 runs through the mounting member 3 along the thickness direction Z. An air guiding member 32 is provided on a side wall of the vent 31 away from the fan 2. Along the thickness direction Z of the mounting member 3, the air guiding member 32 bends towards a direction away from the first heating member 4 and extends close to the fan 2.

During operation of the energy storage system, the first heating member 4 will dissipate heat. If the temperature of the first heating member 4 is excessively high, the energy storage system cannot operate normally. Mounting the first heating member 4 on the air outlet side of the fan 2 can increase the air flow rate around the first heating member 4, thereby improving the heat dissipation effect on the first heating member 4 and improving the heat dissipation effect in the energy storage system. Along the thickness direction Z of the mounting member 3, the mounting member 3 has a first side and a second side arranged opposite to each other, and the first heating member 4 is mounted on the first side of the mounting member 3. The mounting member 3 is arranged on the air outlet side of the fan 2 to divide airflow blown out by the fan 2 into two parts. One part is blown to the first side of the mounting member 3 where the first heating member 4 is provided, and the other part is blown to the second side of the mounting member 3 where no first heating member 4 is provided. Based on limitations of the size of the energy storage system and the mounting position of the fan 2, a flow rate of the in airflow blown to the first side of the mounting member 3 is less than a flow rate of the airflow blown to the second side of the mounting member 3. Therefore, the mounting member 3 is provided with a vent 31, so that two sides of the mounting member 3 in the thickness direction Z are connected to each other, and the air guiding member 32 can transfer the airflow on the second side of the mounting member 3 to the first side, thereby increasing the flow rate of the airflow on the first side of the mounting member 3 and further improving the heat dissipation effect on the first heating member 4.

As shown in FIG. 2, in some embodiments, the first heating member 4 includes a circuit board 41 and a heating element 42. The heating element 42 is mounted on the circuit board 41, and the mounting member 3 is provided with the vent 31 at a position corresponding to the heating element 42.

The circuit board 41 is mounted on the mounting member 3, and the heating element 42 is mounted on a side of the circuit board 41 away from the mounting member 3.

The heating element 42 may be an electronic element such as a relay. During the operation of the energy storage system, the heating element 42 will dissipate heat, causing the temperature at a position where the heating element 42 is provided on the circuit board 41 to rise. The vent 31 is provided at the position corresponding to the heating element 42, so that the airflow on the second side of the mounting member 3 can be blown towards the heating element 42 through the vent 31, thereby improving the heat dissipation effect at the position where the heating element 42 is provided on the circuit board 41.

As shown in FIG. 2, in some embodiments, the heating element 42 is mounted on the side of the circuit board 41 away from the mounting member 3. A support member 5 is arranged between the circuit board 41 and the mounting member 3, and the support member 5 is configured to support the circuit board 41.

The support member 5 provides a gap between the circuit board 41 and the mounting member 3, and the airflow on the second side of the mounting member 3 can be blown into the gap between the circuit board 41 and the mounting member 3 through the vent 31.

The support member 5 is arranged between the circuit board 41 and the mounting member 3, which reduces the possibility of blocking the vent 31 by the circuit board 41 and enables the airflow on the second side of the mounting member 3 to be blown to the circuit board 41 through the vent 31 and to flow in the gap between the circuit board 41 and the mounting member 3, thereby increasing the air flow rate on a side of the circuit board 41 facing the mounting member 3, to improve the heat dissipation effect on the circuit board 41.

In some embodiments, the support member 5 may have a cylindrical structure, and the support member 5 has a smaller diameter, which can reduce the blocking of the airflow between the circuit board 41 and the mounting member 3 while supporting the circuit board 41, thereby improving the heat dissipation efficiency of the circuit board 41.

As shown in FIG. 2, in some embodiments, the energy storage system further includes a second heating member 6. Along the thickness direction Z of the mounting member 3, the second heating member 6 is located on a side of the mounting member 3 away from the first heating member 4.

The second heating member 6 is mounted on the inner wall of the cavity 11 and is located on the air outlet side of the fan 2. The airflow blown out by the fan 2 can increase an air flow rate around the second heating member 6.

Both the first heating member 4 and the second heating member 6 are located on the air outlet side of the fan 2, and along the thickness direction Z of the mounting member 3, the second heating member 6 is located on the side of the mounting member 3 away from the first heating member 4, so that the fan 2 can dissipate heat for the first heating member 4 and the second heating member 6 at the same time, which improves space utilization in the cavity 11 and is conducive to miniaturization of the energy storage system.

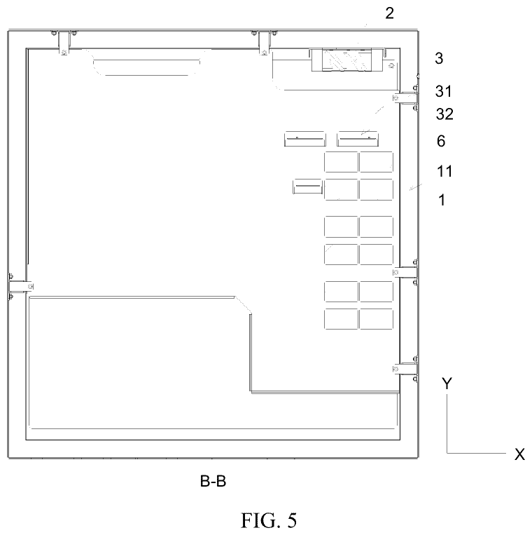

As shown in FIG. 4 and FIG. 5, in some embodiments, the fan 2 is located on a side of the mounting member 3 in a length direction Y, the mounting member 3 is provided with a plurality of vents 31, and the plurality of vents 31 are arranged at intervals along a width direction X of the mounting member 3. Along an air outlet direction of the fan 2, the vents 31 and the second heating member 6 are sequentially arranged.

The first heating member 4 is arranged on one side of the mounting member 3, and a plurality of vents 31 are arranged at intervals in the width direction X of the mounting member 3, which increases the range of flowing of the airflow from the second side of the mounting member 3 to the first heating member 4 and can improve the heat dissipation efficiency of the first heating member 4. Along the air outlet direction of the fan 2, the vents 31 and the second heating member 6 are sequentially arranged, and the airflow on the second side of the mounting member 3 first passes through the vent 31 and is then blown to the second heating member 6, which can reduce the temperature of the airflow blown through the vent 31 to the first heating member 4 and can improve the heat dissipation effect on the first heating member 4.

As shown in FIG. 4 and FIG. 5, in some embodiments, the mounting member 3 is provided with a plurality of vents 31, and the plurality of vents 31 are arranged at intervals along the length direction Y of the mounting member 3. Along a direction perpendicular to the air outlet direction of the fan 2, the vents 31 and the second heating member 6 are arranged side by side.

The plurality of vents 31 are arranged along the length direction Y of the mounting member 3 and are located in an air outlet range of the fan 2, which increases the range of flowing of the airflow on the second side of the mounting member 3 to the first heating member 4 along the length direction Y of the mounting member 3 and can improve the heat dissipation efficiency of the first heating member 4. The air guiding member 32 is provided on a side wall of the vent 31 and bends towards a direction close to the second heating member 6. Along the direction perpendicular to the air outlet direction of the fan 2, the vents 31 and the second heating member 6 are arranged side by side, which can reduce the possibility of interference between the air guiding member 32 and the second heating member 6.

In some embodiments, within the air outlet range of the fan 2, the mounting member 3 may also be provided with the vent 31 at another position, as long as the air guiding member 32 provided on the side wall of the vent 31 does not interfere with the second heating member 6, which can further improve the heat dissipation effect on the first heating member 4.

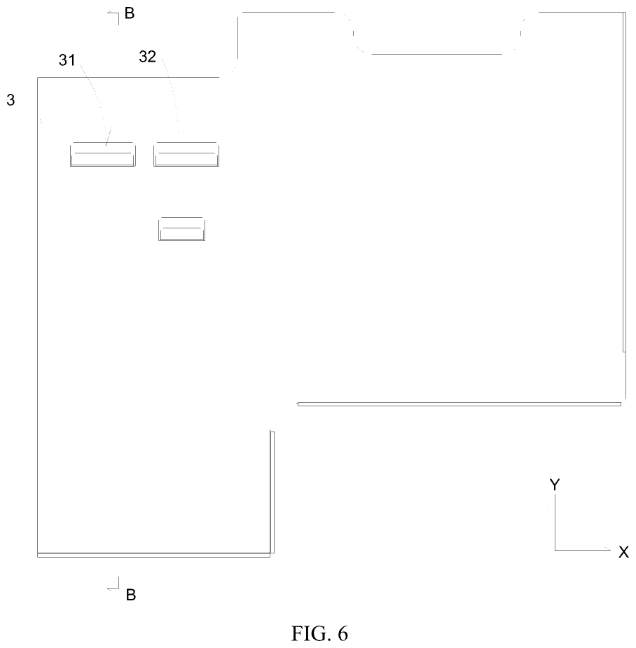

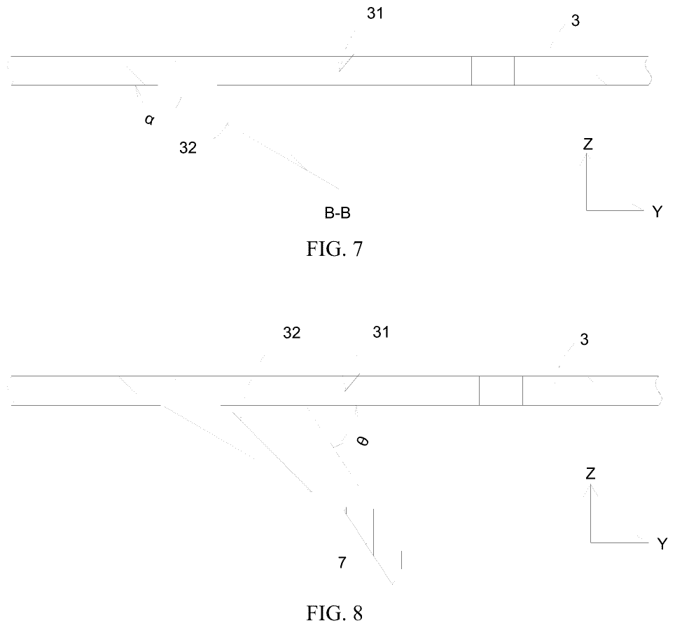

As shown in FIG. 6 and FIG. 7, in some embodiments, the air guiding member 32 provided at the vent 31 is inclined in a direction away from the first heating member 4. An angle between the air guiding member 32 and the mounting member 3 is α, where α ranges from 132° to 138°.

The first heating member 4 is mounted on the first side of the mounting member 3, and the air guiding member 32 is inclined in the direction away from the first heating member 4, so that the air guiding member 32 protrudes from the second side of the mounting member 3 and can guide the airflow from the second side of the mounting member 3 to the first side of the mounting member 3, which increases the air flow rate on the first side of the mounting member 3, thereby improving the heat dissipation effect on the first heating member 4. If the angle between the air guiding member 32 and the mounting member 3 is larger, a length of the air guiding member 32 protruding from the second side of the mounting member 3 may be reduced, which reduces the flow rate of the airflow flowing from the second side of the mounting member 3 along the air guiding member 32 into the first side of the mounting member 3. As a result, the heat dissipation effect on the first heating member 4 is reduced. If the angle between the air guiding member 32 and the mounting member 3 is smaller, the air guiding member 32 may affect the flow rate of the airflow in contact with the air guiding member 32 on the second side of the mounting member 3, thereby reducing a flow rate of the airflow flowing into the first side of the mounting member 3. As a result, the heat dissipation effect on the first heating member 4 is reduced. Therefore, the angle α between the air guiding member 32 and the air outlet direction of the fan 2 may be 132°, 135°, 138°, or the like, which is 135° as an example, which can cause a sufficient flow of airflow to flow along the air guiding member 32 from the second side of the mounting member 3 to the first side of the mounting member 3 and can reduce the influence on an airflow flow rate, to improve the heat dissipation effect on the first heating member 4.

As shown in FIG. 8, in some embodiments, an extension portion 7 is arranged at an end of the air guiding member 32 away from the mounting member 3, and the extension portion 7 bends towards a direction close to the fan 2 and away from the first heating member 4.

The extension portion 7 is arranged at an end portion of the air guiding member 32, which can extend the size of the air guiding member 32 protruding from the second side of the mounting member 3, so that part of the airflow on the second side of the mounting member 3 can contact the extension portion 7 and flow along the extension portion 7 to the air guiding member 32 and then to the first side of the mounting member 3, so as to increase the air flow rate between the first heating member 4 and the mounting member 3, thereby improving the heat dissipation effect on the first heating member 4.

As shown in FIG. 8, in some embodiments, the extension portion 7 arranged at the end portion of the air guiding member 32 extends in a direction close to the fan 2, and an angle between a straight line where the extension portion 7 is located and the mounting member 3 is θ, where θ ranges from 0° to 90°.

The extension portion 7 is configured to extend the size of the air guiding member 32 protruding from the second side of the mounting member 3, so that the airflow on the second side of the mounting member 3 can flow along the extension portion 7 to the air guiding member 32. The angle θ between the straight line where the extension portion 7 is located and the mounting member 3 may be 0°, 45°, 90°, or the like, which is 45° as an example. If the angle θ between the straight line where the extension portion 7 is located and the mounting member 3 is less than 0°, a contact area between the air guiding member 32 and the airflow on the second side of the mounting member 3 may be reduced, and the flow rate of the airflow flowing from the vent 31 into the first side of the mounting member 3 may be reduced. If the angle θ between the straight line where the extension portion 7 and the mounting member 3 is greater than 90°, the airflow on the second side of the mounting member 3 cannot flow along the extension portion 7 to the air guiding member 32, and may also affect the flow rate of the airflow on the second side of the mounting member 3.

In some embodiments, a cross section of the extension portion 7 along the direction perpendicular to the air outlet direction of the fan 2 is in a shape of an arc.

The extension portion 7 is configured to guide the airflow on the second side of the mounting member 3 to the air guiding member 32. The cross section of the extension portion 7 may alternatively be in a shape of a rectangle, V, or the like. When the angle between the extension portion 7 and the air outlet direction of the fan 2 is the same, a contact area between the extension portion 7 and the second side of the mounting member 3 can be increased, thereby increasing the flow rate of the airflow flowing from the second side of the mounting member 3 into the first side of the mounting member 3.

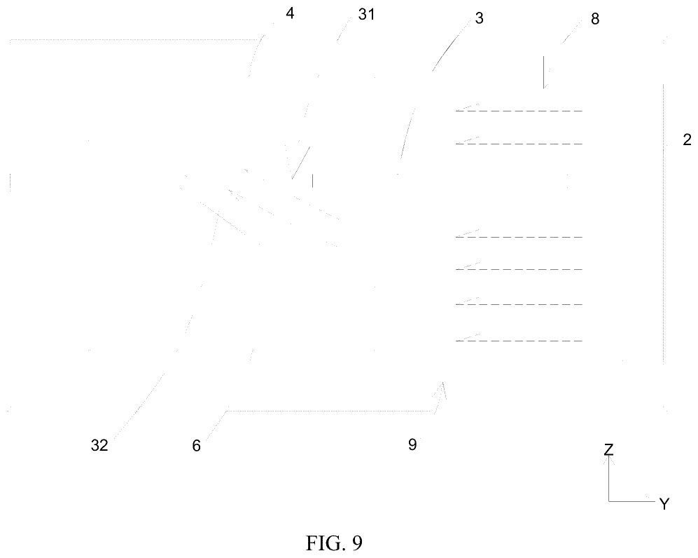

As shown in FIG. 9, some embodiments of the present disclosure further provide a heat dissipation system, applied to the energy storage system according to any one of the above embodiments. The heat dissipation system includes a first heat dissipation channel 8 and a second heat dissipation channel 9. Along the thickness direction Z of the mounting member 3, the first heat dissipation channel 8 is located on a side of the mounting member 3 close to the first heating member 4, the second heat dissipation channel 9 is located on a side of the mounting member 3 away from the first heating member 4. The first heat dissipation channel 8 and the second heat dissipation channel 9 are connected through the vent 31, so that airflow in the second heat dissipation channel 9 passes through the vent 31 and enters the first heat dissipation channel 8.

The mounting member 3 is located on the air outlet side of the fan 2, and along the thickness direction Z of the mounting member 3, the mounting member 3 can divide the airflow blown by the fan 2 into two parts, to form the first heat dissipation channel 8 and the second heat dissipation channel 9. The mounting member 3 is provided with the vent 31 and the air guiding member 32 to enable the first heat dissipation channel 8 to be in communication with the second heat dissipation channel 9 and to enable the airflow in the second heat dissipation channel 9 to flow into the first heat dissipation channel 8, which can increase the flow rate of the airflow in the first heat dissipation channel 8 and improve the heat dissipation capability of the first heat dissipation channel 8.

The first heating member 4 and the second heating member 6 in the energy storage system are respectively arranged in the first heat dissipation channel 8 and the second heat dissipation channel 9, the airflow blown by the fan 2 into the first heat dissipation channel 8 and the second heat dissipation channel 9 dissipates heat to the first heating member 4 and the second heating member 6, and the heat dissipation system can simultaneously dissipate heat to the first heating member 4 and the second heating member 6 through the fan 2, which improves heat dissipation efficiency and space utilization in the energy storage system.

Some embodiments of the present disclosure provide an energy storage system and a heat dissipation system. The heat dissipation system is applied to the energy storage system. The energy storage system includes a box 1. A cavity 11 is provided in the box 1. A fan 2, a mounting member 3, and a first heating member 4 are provided in the cavity 11. The fan 2 is mounted on an inner wall of the cavity 11. The mounting member 3 is also mounted on the inner wall of the cavity 11 and is located on an air outlet side of the fan 2. The first heating member 4 is mounted on one side of the mounting member 3 along a thickness direction Z of the mounting member 3. The fan 2 can increase air flow rates on two sides of the mounting member 3 in the thickness direction Z, and then can increase the air flow rate around the first heating member 4, thereby helping improve the heat dissipation effect on the first heating member 4. The mounting member 3 is provided with a vent 31, an air guiding member 32 is provided on a side of the vent 31 away from the fan 2, and the air guiding member 32 bends towards a direction away from the first heating member 4 and extends close to the fan 2, so that airflow on the other side of the mounting member 3 can flow along the air guiding member 32 to a side of the mounting member 3 where the first heating member 4 is provided, thereby further improving the heat dissipation effect on the first heating member 4.

According to the above embodiments, the present disclosure relates to an energy storage system and a heat dissipation system. The heat dissipation system is applied to the energy storage system. The energy storage system includes a box. A cavity is provided in the box. A fan, a mounting member, and a first heating member are provided in the cavity. The fan is mounted on an inner wall of the cavity. The mounting member is also mounted on the inner wall of the cavity and is located on an air outlet side of the fan. The first heating member is mounted on one side of the mounting member along a thickness direction of the mounting member. The fan can increase air flow rates on two sides of the mounting member in the thickness direction, and then can increase an air flow rate around the first heating member, thereby helping to improve the heat dissipation effect on the first heating member. The mounting member is provided with a vent, an air guiding member is provided on a side of the vent away from the fan. The air guiding member bends away from the first heating member and extends towards the fan, so that airflow on the other side of the mounting member can flow along the air guiding member to a side of the mounting member where the first heating member is provided, thereby further improving the heat dissipation effect on the first heating member.

The above embodiments are merely preferred embodiments of the present disclosure and are not intended to limit the present disclosure. Various changes and modifications can be made to the present disclosure by those skilled in the art. Any modifications, equivalent substitutions and improvements made within the spirit and principle of the present disclosure shall fall into the protection scope of the present disclosure.

What is claimed is:

1. An energy storage system, comprising:
a box, wherein a cavity is provided in the box;
a fan located in the cavity and mounted on an inner wall of the cavity;
a mounting member connected to the inner wall of the cavity and located on an air outlet side of the fan; and
a first heating member mounted on one side of the mounting member along a thickness direction of the mounting member;
wherein the fan is configured to increase air flow rates on two sides of the mounting member along the thickness direction, the mounting member comprises a vent, the vent runs through the mounting member along the thickness direction, an air guiding member is provided on a side wall of the vent away from the fan, and along the thickness direction of the mounting member, the air guiding member bends away from the first heating member and extends towards the fan.

2. The energy storage system according to claim 1, wherein the first heating member comprises a circuit board and a heating element mounted on the circuit board, and the mounting member is provided with the vent at a position corresponding to the heating element.

3. The energy storage system according to claim 2, wherein the heating element is mounted on a side of the circuit board away from the mounting member, a support member is arranged between the circuit board and the mounting member, and the support member is configured to support the circuit board.

4. The energy storage system according to claim 3, wherein the support member is configured to provide a gap between the circuit board and the mounting member so that air flow is capable of being blown into the gap.

5. The energy storage system according to claim 3, wherein the support member has a cylindrical structure.

6. The energy storage system according to claim 1, further comprising a second heating member located, along the thickness direction of the mounting member, on a side of the mounting member away from the first heating member.

7. The energy storage system according to claim 6, wherein the fan is located on a side of the mounting member along a length direction of the mounting member, the mounting member is provided with a plurality of vents arranged at intervals along a width direction of the mounting member, and along an air outlet direction of the fan, the vents and the second heating member are sequentially arranged.

8. The energy storage system according to claim 6, wherein the mounting member is provided with a plurality of vents arranged at intervals along a length direction of the mounting member, and along a direction perpendicular to an air outlet direction of the fan, the vents and the second heating member are arranged side by side.

9. The energy storage system according to claim 1, wherein an angle between the air guiding member and the mounting member ranges from 132° to 138°.

10. The energy storage system according to claim 9, wherein the angle between the air guiding member and the mounting member is 135°.

11. The energy storage system according to claim 1, wherein an extension portion is arranged at an end of the air guiding member away from the mounting member, and the extension portion bends towards to the fan and away from the first heating member.

12. The energy storage system according to claim 11, wherein an angle between a straight line where the extension portion is located and the mounting member ranges from 0° to 90°.

13. The energy storage system according to claim 12, wherein the angle between a straight line where the extension portion is located and the mounting member is 45°.

14. The energy storage system according to claim 11, wherein a cross section of the extension portion is in a shape of an arc, a rectangle or a V-shape.

15. A heat dissipation system, applied to an energy storage system, wherein the energy storage system comprises:
a box, wherein a cavity is provided in the box;
a fan located in the cavity and mounted on an inner wall of the cavity;
a mounting member connected to the inner wall of the cavity and located on an air outlet side of the fan; and
a first heating member mounted on one side of the mounting member along a thickness direction of the mounting member;
wherein the fan is configured to increase air flow rates on two sides of the mounting member along the thickness direction, the mounting member comprises a vent, the vent runs through the mounting member along the thickness direction, an air guiding member is provided on a side wall of the vent away from the fan, and along the thickness direction of the mounting member, the air guiding member bends away from the first heating member and extends towards the fan,
wherein the heat dissipation system comprises a first heat dissipation channel and a second heat dissipation channel, along the thickness direction of the mounting member, the first heat dissipation channel is located on a side of the mounting member close to the first heating member, the second heat dissipation channel is located on a side of the mounting member away from the first heating member, and the first heat dissipation channel and the second heat dissipation channel are communicated through the vent, so that airflow in the second heat dissipation channel passes through the vent and enters into the first heat dissipation channel.
